(19) United States
(12) Patent Application Publication
(10) Pub. No.: US 2024/0040912 A1
(43) Pub. Date: Feb. 1, 2024

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: He JIANG, Wuhan, Hubei (CN); Liang SUN, Wuhan, Hubei (CN)

(21) Appl. No.: 17/597,106

(22) PCT Filed: Dec. 20, 2021
(86) PCT No.: PCT/CN2021/139812

§ 371 Date: Dec. 27, 2021

(30) Foreign Application Priority Data
Dec. 13, 2021 (CN) 202111515418.2

(51) Int. Cl. H10K 59/80; H10K 59/40

(52) U.S. Cl. CPC H10K 59/879; H10K 59/40

(57) ABSTRACT

A display panel and a display device are disclosed. The display panel includes a substrate, a light emitting layer, a protective layer and a light adjusting layer. The protective layer is located on the side of the light emitting layer far away from the substrate, the protective layer includes a plurality of stop blocks disposed corresponding to gaps between light emitting pixels, and the light adjusting layer is located between adjacent two stop blocks and covers the stop blocks. A refractive index of the protective layer is less than a refractive index of the light adjusting layer, and the light is totally reflected at a junction between the light adjusting layer and the stop block, which improves the forward light efficiency and light output efficiency.

### BACKGROUND

### Technical Field

This application relates to the technical field of display, in particular to a display panel and a display device.

### Related Art

An organic light emitting diode (OLED) display panel consists of a variety of device film layers and light emitting layers. When light is emitted from the light emitting layer, due to the reflection and refraction of the device film layer, most of the light is emitted at a large angle or cannot escape into the air due to total reflection on the surface of the device film layer, resulting in low light extraction efficiency and light output rate and thus increasing the power consumption.

### SUMMARY

### Technical Problem

The embodiment of this application provides a display panel and a display device to solve the technical problem that most of light of an existing display panel is emitted at a large angle or cannot escape into the air due to total reflection on the surface of the device film layer, resulting in low light extraction efficiency and light output rate.

### Technical Solution

To resolve the foregoing problem, the technical solutions provided in this application are as follows:

This application provides a display panel, comprising
a substrate;
a light emitting layer, disposed on the substrate and comprising a plurality of light emitting pixels, there being a gap between adjacent two light emitting pixels;
a protective layer, disposed on the side of the light emitting layer away from the substrate, the protective layer comprising a plurality of stop blocks distributed in an array, the plurality of stop blocks being disposed corresponding to the plurality of gaps in one-to-one correspondence, the material of the protective layer comprising one or more of acrylics, siloxanes and polyimides; and
a light adjusting layer, disposed between adjacent two stop blocks and covering the stop blocks, wherein a refractive index of the protective layer is less than a refractive index of the light adjusting layer.

According to the display panel provided by this application, the display panel further comprises a polarizer, the polarizer is disposed on the side of the protective layer away from the substrate, and the polarizer at least comprises a pressure-sensitive adhesive layer, a phase difference layer, a polarizing layer and a protective film sequentially stacked away from the substrate, wherein the pressure-sensitive adhesive layer also serves as the light adjusting layer.

According to the display panel provided by this application, at least part of region of the pressure-sensitive adhesive layer is doped with high-refractive-index particles, and/or the protective layer is doped with low-refractive-index particles.

According to the display panel provided by this application, the high-refractive-index particles and the low-refractive-index particles are colorless and transparent refraction particles.

According to the display panel provided by this application, the high-refractive-index particles comprise one or more of zirconium oxide particles, titanium oxide particles, aluminum oxide particles and zirconium dioxide particles, and the low-refractive-index particles comprise one or more of silver, copper and silicon dioxide.

According to the display panel provided by this application, a mass ratio of the high-refractive-index particles to the pressure-sensitive adhesive layer is in a range of 1% to 40%.

According to the display panel provided by this application, the refractive index of the light adjusting layer is in a range of 1.5 to 2, and the refractive index of the protective layer is in a range of 1.1 to 1.4.

According to the display panel provided by this application, a thickness of the light adjusting layer is in a range of 10 microns to 100 microns, and a thickness of the protective layer is in a range of 1 micron to 5 microns.

According to the display panel provided by this application, a cross-sectional shape of the stop block is one of a regular triangle and a regular trapezoid.

According to the display panel provided by this application, the display panel further comprises:
a packaging layer, covering the light emitting layer; and
a touch layer, disposed on the side of the packaging layer away from the substrate, the protective layer being disposed on the side of the touch layer away from the substrate.

This application provides a display panel, comprising:
a substrate;
a light emitting layer, disposed on the substrate and comprising a plurality of light emitting pixels, there being a gap between adjacent two light emitting pixels;
a protective layer, disposed on the side of the light emitting layer away from the substrate, the protective layer comprising a plurality of stop blocks distributed in an array, the plurality of stop blocks being disposed corresponding to the plurality of gaps in one-to-one correspondence; and
a light adjusting layer, disposed between adjacent two stop blocks and covering the stop blocks, wherein a refractive index of the protective layer is less than a refractive index of the light adjusting layer.

According to the display panel provided by this application, the display panel further comprises a polarizer, the polarizer is disposed on the side of the protective layer away from the substrate, and the polarizer at least comprises a pressure-sensitive adhesive layer, a phase difference layer, a polarizing layer and a protective film sequentially stacked away from the substrate, wherein the pressure-sensitive adhesive layer also serves as the light adjusting layer.

According to the display panel provided by this application, at least part of region of the pressure-sensitive adhesive layer is doped with high-refractive-index particles, and/or the protective layer is doped with low-refractive-index particles.

According to the display panel provided by this application, the high-refractive-index particles comprise one or more of zirconium oxide particles, titanium oxide particles, aluminum oxide particles or zirconium dioxide particles, and the low-refractive-index particles comprise one or more of silver, copper or silicon dioxide.

According to the display panel provided by this application, a mass ratio of the high-refractive-index particles to the pressure-sensitive adhesive layer is in a range of 1% to 40%.

According to the display panel provided by this application, the refractive index of the light adjusting layer is in a range of 1.5 to 2, and the refractive index of the protective layer is in a range of 1.1 to 1.4.

According to the display panel provided by this application, a thickness of the light adjusting layer is in a range of 10 microns to 100 microns, and a thickness of the protective layer is in a range of 1 micron to 5 microns.

According to the display panel provided by this application, a cross-sectional shape of the stop block is one of a regular triangle and a regular trapezoid.

According to the display panel provided by this application, the display panel further comprises:
a packaging layer, covering the light emitting layer; and
a touch layer, disposed on the side of the packaging layer away from the substrate, the protective layer being disposed on the side of the touch layer away from the substrate.

This application provides a display device, comprising a display panel, and the display panel comprises:
a substrate;
a light emitting layer, disposed on the substrate and comprising a plurality of light emitting pixels, there being a gap between adjacent two light emitting pixels;
a protective layer, disposed on the side of the light emitting layer away from the substrate, the protective layer comprising a plurality of stop blocks distributed in an array, the plurality of stop blocks being disposed corresponding to the plurality of gaps in one-to-one correspondence; and
a light adjusting layer, disposed between adjacent two stop blocks and covering the stop blocks, wherein a refractive index of the protective layer is less than a refractive index of the light adjusting layer.

Beneficial Effects

This application has the following beneficial effects: for the display panel and the display device provided by this application, the protective layer and the light adjusting layer are disposed on the side of the light emitting layer away from the substrate, the protective layer includes a plurality of stop blocks distributed in an array, the plurality of stop blocks is disposed corresponding to the plurality of gaps between adjacent two light emitting pixels in one-to-one correspondence, and the light adjusting layer is disposed between adjacent two stop blocks and covers the stop blocks; since a refractive index of the protective layer is less than a refractive index of the light adjusting layer, the light emitted by the light emitting pixels is totally reflected at a junction between the light adjusting layer and the stop block, thus making large-angle light converge to a middle region, which reduces the large-angle loss of light and the total reflection loss between film layers, and is beneficial to improving the forward light efficiency and light output efficiency of the display panel.

### BRIEF DESCRIPTION OF THE DRAWINGS

To describe the technical solutions in the embodiments of this application more clearly, the following briefly describes the accompanying drawings required for describing the embodiments. Apparently, the accompanying drawings in the following description show merely some embodiments of this application, and a person skilled in the art may still derive other drawings from these accompanying drawings without creative efforts.

FIG. 1 illustrates a schematic sectional structural diagram of a first display panel provided by an embodiment of this application.

FIG. 2 illustrates a schematic sectional structural diagram of a second display panel provided by an embodiment of this application.

FIG. 3 illustrates a schematic sectional structural diagram of a third display panel provided by an embodiment of this application.

FIG. 4 illustrates a schematic sectional structural diagram of a fourth display panel provided by an embodiment of this application.

FIG. 5 illustrates a flowchart of a method for fabricating a display panel provided by an embodiment of this application.

FIG. 5A to FIG. 5E illustrate flowcharts of a method for fabricating a display panel provided by an embodiment of this application.

### DESCRIPTION OF SYMBOLS

10-substrate; 20-light emitting layer; 201-light emitting pixel; 202-gap; 30-protective layer; 301-stop block 302-low-refractive-index particle; 40-light adjusting layer; 401-high-refractive-index particle; 402.-microlens module; 50-polarizer; 501-pressure-sensitive adhesive layer; 502-phase difference layer; 503-polarizing layer; 504-protective film; 505-carrier; 60-packaging layer; 70-touch layer; 80-driving circuit layer; and 90-pixel definition layer.

### DETAILED DESCRIPTION

The technical solutions of embodiments of this application are clearly and completely described below with reference to the accompanying drawings in embodiments of this application. Apparently, the described embodiments are merely a part rather than all of the embodiments of this application. All other embodiments obtained by a person skilled in the art based on the embodiments of this application without creative efforts shall fall within the protection scope of this application. It should be understood that the specific implementations described herein are merely for illustrating and explaining this application and are not intended to limit this application. In this application, unless otherwise specified, orientation terms such as “up” and “down” generally refer to the up and down of a device in an actual use or a working state, and specifically, refer to graphical directions of the accompanying drawings; and “inside” and “outside” refer to the inside and outside relative to the contour of the device.

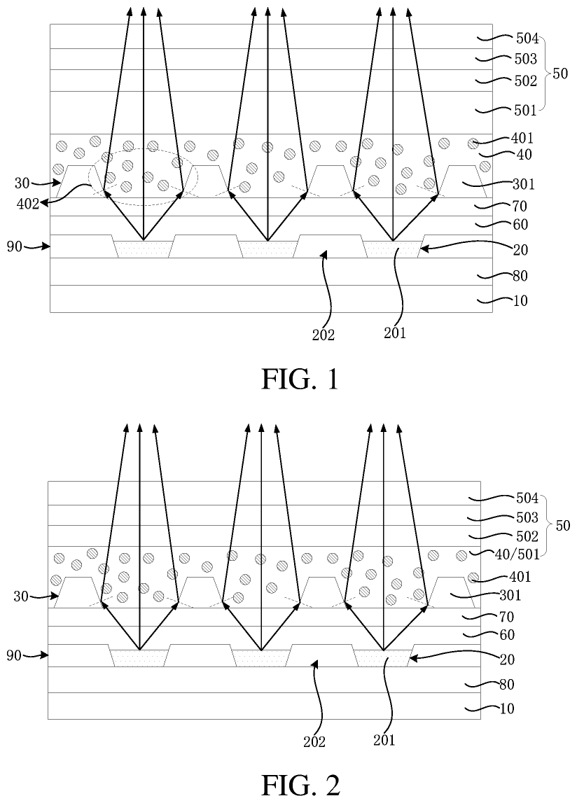

Referring to FIG. 1. FIG. 1 is a schematic sectional structural diagram of a first display panel provided by an embodiment of this application. The display panel provided by the embodiment of this application includes a substrate 10, a light emitting layer 20, a protective layer 30 and a light adjusting layer 40.

The light emitting layer 20 is disposed on the substrate 10. The light emitting layer 20 includes a plurality of light emitting pixels 201. There is a gap 202 between adjacent two light emitting pixels 201. The plurality of light emitting pixels 201 at least includes a red light emitting pixel, a green light emitting pixel and a blue light emitting pixel. The protective layer 30 is disposed on the side of the light emitting layer 20 away from the substrate 10. The protective layer 30 includes a plurality of stop blocks 301 distributed in an array. The plurality of stop blocks 301 is disposed corresponding to the plurality of gaps 202 in one-to-one correspondence. The light adjusting layer 40 is disposed between adjacent two stop blocks 301 and covers the stop blocks 301.

It can be understood that, in the embodiment of this application, the protective layer 30 and the light adjusting layer 40 are disposed, and the light adjusting layer 40 is filled between adjacent two stop blocks 301 so that a plurality of microlens modules 402 distributed in an array is formed on the side of the light adjusting layer 40 close to the substrate, and the microlens modules 402 are used to transmit the light emitted by the light emitting pixels 201. Since a refractive index of the protective layer 30 is less than a refractive index of the light adjusting layer 40, that is, a refractive index of the stop block 301 is less than a refractive index of the microlens module 402, the light emitted by the light emitting pixel 201 is totally reflected at a junction between the microlens module 402 and the stop block 301, thus making large-angle light converge to a middle region, which reduces the large-angle loss of light and the total reflection loss between the film layers, and is beneficial to improving the forward light efficiency and light output efficiency of the display panel.

Specifically, in one implementation, a material of the light adjusting layer 40 may be a pressure-sensitive adhesive (polysulfonamide, PSA) or Optically Clear Adhesive (OCA). When the material of the light adjusting layer 40 is OCA, the light adjusting layer 40 may be formed on the side of the protective layer 30 away from the substrate 10 by adopting a coating process.

Referring to FIG. 1, the display panel further includes a polarizer 50. The polarizer 50 is disposed on the side of the light adjusting layer 40 away from the substrate 10. The polarizer 50 at least includes a pressure-sensitive adhesive layer 501, a phase difference layer 502, a polarizing layer 503 and a protective film 504 stacked together.

Specifically, the pressure-sensitive adhesive layer 501 is used to bond the phase difference layer 502 to the side of the protective layer 30 away from the substrate 10. The material of the pressure-sensitive adhesive layer 501 includes polysulfonamide (PSA). PSA is a kind of adhesive sensitive to pressure. The protective film 504 is used to support and protect the polarizing layer 503.

In this implementation, light emitted by the light emitting pixel 201 is totally reflected at a junction between the light adjusting layer 40 and the stop block 301, thus making large-angle light to converge to a middle region, sequentially pass through the pressure-sensitive adhesive layer 501, the phase difference layer 502, the polarizing layer 503 and the protective film 504, and then be emitted into external air.

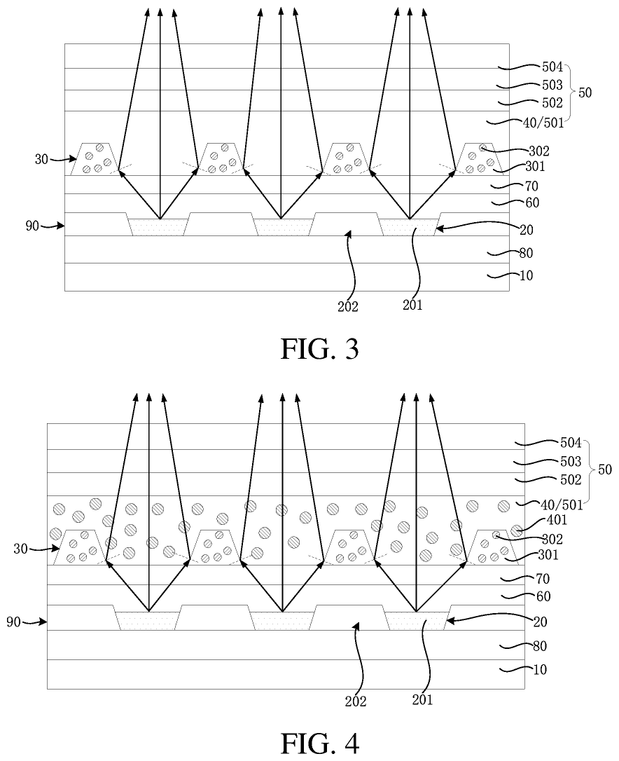

Further, in another implementation, referring to FIG. 2, FIG. 2 is a schematic sectional structural diagram of a second display panel provided by the embodiment of this application. A difference of FIG. 2 from FIG. 1 is that the polarizer 50 is disposed on the side of the protective layer 30 away from the substrate 10, and the pressure-sensitive adhesive layer 501 also serves as the light adjusting layer 40. In this case, light emitted by the light emitting pixels 201 is totally reflected at a junction between the pressure-sensitive adhesive layer 501 and the stop block 301, thus making large-angle light to converge to a middle region, sequentially pass through the phase difference layer 502, the polarizing layer 503 and the protective film 504, and then be emitted into external air.

It should be noted that in this implementation, by making the pressure-sensitive adhesive layer 501 also serve as the light adjusting layer 40, compared with the implementation in FIG. 1, there is no need to add a light adjusting layer 40 between the polarizer 50 and the protective layer 30. Moreover, when the material of the light adjusting layer 40 is PSA, it is difficult to form by coating PSA through an existing coating process due to the poor fluidity of PSA. Since the polarizer 50 itself has the pressure-sensitive adhesive layer 501, it helps to reduce the process and reduce the cost. In addition, since a film layer is omitted, an overall thickness of the display panel is reduced, which helps to realize the lightness and thinness of the display panel.

The materials of the pressure-sensitive adhesive layer 501 and the protective layer 30 are organic polymers. Generally, a refractive index difference between different organic polymers is generally small. That is, a refractive index difference between different film layers is generally small. For example, a refractive index difference between the pressure-sensitive adhesive layer 501 and the protective layer 30 is small, then, it is difficult to achieve the purpose that the refractive index of the pressure-sensitive adhesive layer 501 is greater than the refractive index of the protective layer 30 by changing the specific organic polymer material. Therefore, the embodiment of this application can achieve the above purpose by increasing the refractive index of the light adjusting layer 40 or reducing the refractive index of the protective layer 30.

Specifically, in this embodiment of this application, at least part of region of the pressure-sensitive adhesive layer 501 is doped with high-refractive-index particles 401, and/or the stop blocks 301 are doped with low-refractive-index particles 302. These ways are briefly described as follows:

Continuously referring to FIG. 2, in one implementation, at least part of region of the pressure-sensitive adhesive layer 501 is doped with high-refractive-index particles 401, so that an average refractive index of the pressure-sensitive adhesive layer 501 increases, that is, the average refractive index of the light adjusting layer 40 increases, and then the refractive index of the light adjusting layer 40 is greater than the refractive index of the protective layer 30.

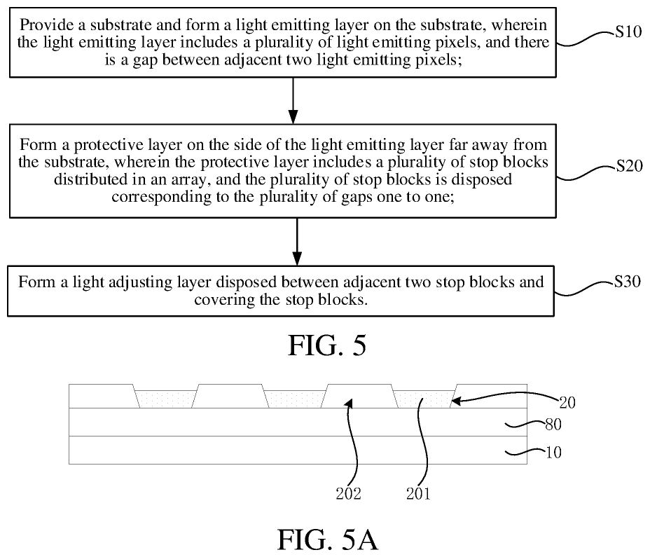

In one implementation, referring to FIG. 3, FIG. 3 is a schematic sectional structural diagram of a third display panel provided by the embodiment of this application. A difference of FIG. 3 from FIG. 2 is that the protective layer 30 is doped with low-refractive-index particles 302, so that the average refractive index of the protective layer 30 increases, and then the refractive index of the light adjusting layer 40 is greater than the refractive index of the protective layer 30.

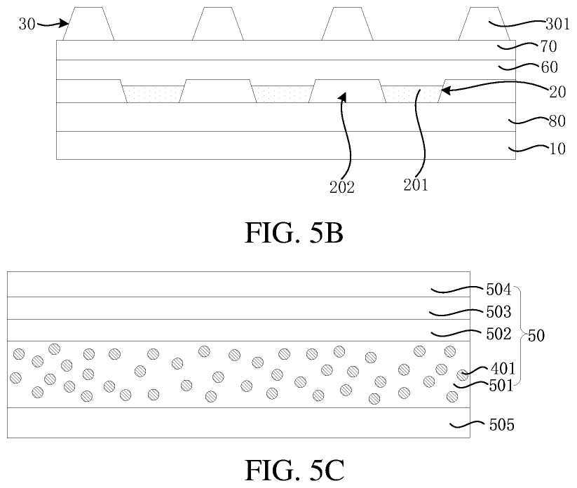

In one implementation, referring to FIG. 4, FIG. 4 is a schematic sectional structural diagram of a fourth display panel provided by the embodiment of this application. A difference of FIG. 4 from FIG. 2 is that at least part of region of the pressure-sensitive adhesive layer 501 is doped with high-refractive-index particles 401, and the protective layer 30 is doped with low-refractive-index particles 302, so that the average refractive index of the light adjusting layer 40 increases, the average refractive index of the protective layer 30 increases, and then the refractive index of the light adjusting layer 40 is further greater than the refractive index of the protective layer 30.

Specifically, the refractive index of the light adjusting layer 40 is in a range of 1.5-2, and the refractive index of the protective layer 30 is in a range of 1.1-1.4. Optionally, the refractive index of the light adjusting layer 40 may be one of 1.5, 1.6, 1.7, 1.8, 1.9, and 2.0, and the refractive index of the protective layer 30 may be one of 1.1, 1.15, 1.2, 1.25, 1.3, 1.35, and 1.4.

Specifically, the high-refractive-index particles 401 and the low-refractive-index particles 302 are colorless and transparent refraction particles, so that light can pass through the high-refractive-index particles 401 and the low-refractive-index particles 302 without affecting the transmittance.

Optionally, the high-refractive-index particles 401 include one or more of zirconium oxide particles, titanium oxide particles, aluminum oxide particles and zirconium dioxide particles, and a diameter of the high-refractive-index particle 401 is within a range of 1 nm to 300 nm; the low-refractive-index particles 302 include one or more of silver, copper and silicon dioxide, and a diameter of the low-refractive-index particle 302 is in a range of 1 nm to 300 nm.

Specifically, a mass ratio of the high-refractive-index particles 401 to the light adjusting layer 40 is in a range of 1% to 40%; and a mass ratio of the low-refractive-index particles 302 to the protective layer 30 is in a range of 1% to 40%.

Specifically, a thickness of the light adjusting layer 40 is in a range of 10 microns to 100 microns. The reason is that, on the one hand, the thickness of the light adjusting layer 40 should not be too small in order to prevent poor surface flatness of the side of the light adjusting layer 40 away from the substrate 10 caused by the fact that the thickness of the light adjusting layer 40 cannot effectively cover the stop blocks 301; on the other hand, the light adjusting layer 40 needs to ensure that it has sufficient adhesion to bond the phase difference layer 502 to the side of the protective layer 30 away from the substrate 10 in order to prevent the polarizer 50 from falling off.

Specifically, a thickness of the protective layer 30 is in a range of 1 micron to 5 microns, that is, a thickness of each stop block 301 is in a range of 1 micron to 5 microns, so that all the large-angle light emitted by the light emitting pixels 201 can fully enter a junction between each stop block 301 and the light adjusting layer 40, thus making as much light as possible to converge to a middle region, which is beneficial to further reducing the large-angle loss of light and the total reflection loss between the film layers, and further improving the forward light efficiency and light output efficiency of the display panel.

Specifically, the material of the protective layer 30 includes one or more of acrylics, siloxanes and polyimides. Optionally, the material of the protective layer 30 is any one of colorless polyimide, acrylic resin, epoxy resin, silicone resin, polydimethylsiloxane and hexamethyldisiloxane.

Specifically, a sectional shape of the stop block 301 is one of a regular triangle and a regular trapezoid. For example, the sectional shape of the stop block 301 in FIG. 1 and FIG. 4 is a regular trapezoid.

Of course, the sectional shape of the stop block 301 may also be other shapes, as long as the light emitted by the light emitting pixels 201 can be totally reflected at a junction between the light adjusting layer 40 and the stop block 301, and the totally reflected light is emitted to a light output surface of the display panel. In this embodiment of this application, the sectional shape of the stop block 301 is not specially limited.

Further, an orthographic projection of the stop block 301 on the substrate 10 is located in an orthographic projection of the gap 202 on the substrate 10, so as to avoid affecting the normal light output of the light emitting pixels 201.

Specifically, a width of the side of the stop block 301 close to the substrate 10 is in a range of 5 microns to 50 microns, which should be specifically determined according to a size of the gap 202.

Further, the display panel further includes a driving circuit layer 80 and a pixel definition layer 90. The driving circuit layer 80 is disposed between the substrate 10 and the light emitting layer 20. The driving circuit layer 80 includes a plurality of pixel driving circuits for driving the plurality of light emitting pixels 201 to emit light. The pixel definition layer 90 is disposed on the side of the driving circuit layer 80 away from the substrate 10. The pixel definition layer 90 defines a plurality of pixel openings. The light emitting layer is disposed in the pixel openings, and the gap 202 is located between adjacent two pixel openings.

Further, the display panel may adopt a Direct On Cell Touch (DOT) structure to form an electronic device with a touch function. Specifically, the display panel further includes a packaging layer 60 and a touch layer 70. The packaging layer 60 covers the light emitting layer 20. The touch layer 70 is disposed on the side of the packaging layer 60 away from the substrate 10. The protective layer 30 is disposed on the side of the touch layer 70 away from the substrate 10.

Specifically, the packaging layer 60 may adopt a thin film packaging structure. The thin film packaging structure usually includes a plurality of layers of organic films and a plurality of layers of inorganic films stacked together. A surface of the thin film packaging structure is an inorganic packaging film, such as zinc oxide or other inorganic oxides. The touch layer 70 includes at least one insulating dielectric layer covering the packaging layer and a plurality of touch modules located in the insulating dielectric layer. The plurality of touch modules is located directly above the gaps 202.

It should be noted that the technical solution provided by this application is also applicable to display panels without the DOT structure, and display panels with any structure using the technical solution provided by this application are within the scope of protection of this application.

Further, the display panel further includes a cover plate (not shown). The cover plate is disposed on the side of the polarizer 50 away from the substrate 10. The cover plate may be a transparent glass substrate 10.

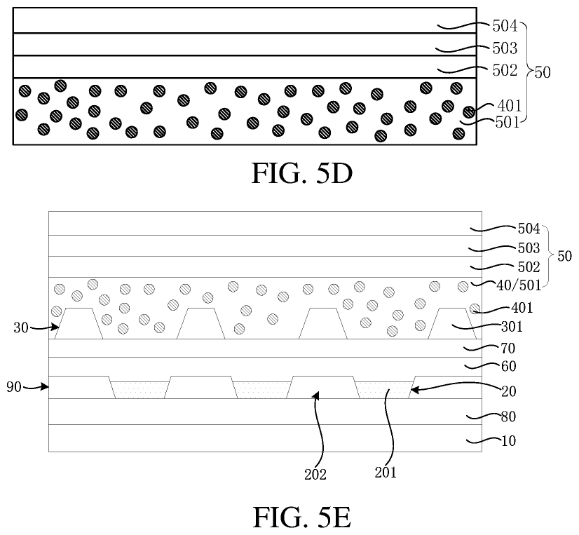

Referring to FIG. 5, FIG. 5A to FIG. 5E. FIG. 5 is a flowchart of a method for fabricating a display panel provided by an embodiment of this application. FIG. 5A to FIG. 5E are flowcharts of a method for fabricating a display panel provided by an embodiment of this application.

The embodiment of this application further provides a method for fabricating a display panel. Taking the display panel in FIG. 2 as an example, the method includes the following steps:

S10: Provide a substrate 10 and form a light emitting layer 20 on the substrate 10. The light emitting layer 20 includes a plurality of light emitting pixels 201. There is a gap 202 between adjacent two light emitting pixels 201.

Specifically, referring to FIG. 5A, before forming the light emitting layer 20, step S10 further includes forming a driving circuit layer 80 on the substrate 10; and forming a pixel definition layer 90 on the side of the driving circuit layer 80 away from the substrate 10. The pixel definition layer 90 defines a plurality of pixel openings.

The light emitting layer 20 may also be formed of a light emitting material filled in the pixel openings by adopting ink-jet printing.

S20: Form a protective layer 30 on the side of the light emitting layer 20 away from the substrate 10. The protective layer 30 includes a plurality of stop blocks 301 distributed in an array. The plurality of stop blocks 301 is disposed corresponding to the plurality of gaps 202 in one-to-one correspondence.

Specifically, referring to FIG. 5B, before forming the protective layer 30, step S20 further includes forming a packaging layer 60 covering the light emitting pixels 201; and forming a touch layer 70 on the side of the packaging layer 60 away from the substrate 10.

Forming the stop block 301 includes the following steps: firstly, coating a protective layer material on a whole side of the touch layer 70 away from the substrate 10, and then performing exposure development etching on the protective layer material by adopting a yellow light process to form the plurality of stop blocks 301.

S30: Form a light adjusting layer 40 disposed between adjacent two stop blocks and covering the stop blocks 301.

Specifically, referring to FIG. 5C, FIG. 5D and FIG. 5E, step S30 further includes the following steps:

S301: providing a polarizer 50; and

S302: disposing the polarizer 50 on the side of the protective layer 30 away from the substrate 10. A pressure-sensitive adhesive layer 501 of the polarizer 50 also serves as the light adjusting layer 40.

Step S301 includes the following steps:
providing a carrier 505 and forming a pressure-sensitive adhesive layer 501 on the carrier 505, wherein the pressure-sensitive adhesive layer 501 is doped with high-refractive-index particles 401;
sequentially forming a phase difference layer 502, a polarizing layer 503 and a protective film 504 on the side of the pressure-sensitive adhesive layer 501 away from the carrier 505; and
peeling off the carrier 505.

Further, the method for fabricating the display panel further includes the following step:

S40: Form a cover plate on the side of the polarizer 50 away from the substrate 10.

The embodiment of this application further provides a display device. The display device includes the display panel in the above embodiment. The display device may be any product or component with a display function, such as a mobile phone, a tablet computer, a TV, a display, a notebook computer, a digital photo frame, or a navigator.

This application has the following beneficial effects: for the display panel and the display device provided by this application, the protective layer and the light adjusting layer are disposed on the side of the light emitting layer away from the substrate, the protective layer includes a plurality of stop blocks distributed in an array, the plurality of stop blocks is disposed corresponding to the plurality of gaps between adjacent two light emitting pixels in one-to-one correspondence, and the light adjusting layer is disposed between adjacent two stop blocks and covers the stop blocks; since a refractive index of the protective layer is less than a refractive index of the light adjusting layer, the light emitted by the light emitting pixels is totally reflected at a junction between the light adjusting layer and the stop block, thus making large-angle light converge to a middle region, which reduces the large-angle loss of light and the total reflection loss between film layers, and is beneficial to improving the forward light efficiency and light output efficiency of the display panel.

In summary, this application has been disclosed through preferred embodiments; however, the preferred embodiments are not intended to limit this application, and a person of ordinary skill in the art can make various modifications and improvements without departing from the spirit and scope of this application; therefore, the protection scope of this application should be subject to the scope defined by the claims.

What is claimed is:

1. A display panel, comprising:
a substrate;
a light emitting layer, disposed on the substrate and comprising a plurality of light emitting pixels, wherein there is a gap between adjacent two light emitting pixels;
a protective layer, disposed on the side of the light emitting layer away from the substrate, wherein the protective layer comprises a plurality of stop blocks distributed in an array, the plurality of stop blocks are disposed corresponding to the plurality of gaps in one-to-one correspondence, a material of the protective layer comprises one or more of acrylics, siloxanes or polyimides; and
a light adjusting layer, disposed between adjacent two stop blocks and covering the stop blocks, wherein a refractive index of the protective layer is less than a refractive index of the light adjusting layer.

2. The display panel according to claim 1, further comprising a polarizer, wherein the polarizer is disposed on the side of the protective layer away from the substrate, and the polarizer at least comprises a pressure-sensitive adhesive layer, a phase difference layer, a polarizing layer and a protective film sequentially stacked away from the substrate, wherein the pressure-sensitive adhesive layer also serves as the light adjusting layer.

3. The display panel according to claim 2, wherein at least part of region of the pressure-sensitive adhesive layer is doped with high-refractive-index particles, or the protective layer is doped with low-refractive-index particles.

4. The display panel according to claim 3, wherein the high-refractive-index particles and the low-refractive-index particles are colorless and transparent refraction particles.

5. The display panel according to claim 3, wherein the high-refractive-index particles comprise one or more of zirconium oxide particles, titanium oxide particles, aluminum oxide particles or zirconium dioxide particles, and the low-refractive-index particles comprise one or more of silver, copper or silicon dioxide.

6. The display panel according to claim 3, wherein a mass ratio of the high-refractive-index particles to the pressure-sensitive adhesive layer ranges from 1% to 40%.

7. The display panel according to claim 2, wherein the refractive index of the light adjusting layer ranges from 1.5 to 2, and the refractive index of the protective layer ranges from 1.1 to 1.4.

8. The display panel according to claim 2, wherein a thickness of the light adjusting layer ranges from 10 microns to 100 microns, and a thickness of the protective layer ranges from 1 micron to 5 microns.

9. The display panel according to claim 1, wherein a cross-sectional shape of the stop block is one of a regular triangle or a regular trapezoid.

10. The display panel according to claim 1, further comprising:
a packaging layer, covering the light emitting layer; and
a touch layer, disposed on the side of the packaging layer away from the substrate, wherein the protective layer is disposed on the side of the touch layer away from the substrate.

11. A display panel, comprising
a substrate;
a light emitting layer, disposed on the substrate and comprising a plurality of light emitting pixels, wherein there is a gap between adjacent two light emitting pixels;
a protective layer, disposed on the side of the light emitting layer away from the substrate, wherein the protective layer comprises a plurality of stop blocks distributed in an array, the plurality of stop blocks are disposed corresponding to the plurality of gaps in one-to-one correspondence; and
a light adjusting layer, disposed between adjacent two stop blocks and covering the stop blocks, wherein a refractive index of the protective layer is less than a refractive index of the light adjusting layer.

12. The display panel according to claim 11, further comprising a polarizer, wherein the polarizer is disposed on the side of the protective layer away from the substrate, and the polarizer at least comprises a pressure-sensitive adhesive layer, a phase difference layer, a polarizing layer and a protective film sequentially stacked away from the substrate, wherein the pressure-sensitive adhesive layer also serves as the light adjusting layer.

13. The display panel according to claim 12, wherein at least part of region of the pressure-sensitive adhesive layer is doped with high-refractive-index particles, or the protective layer is doped with low-refractive-index particles.

14. The display panel according to claim 13, wherein the high-refractive-index particles comprise one or more of zirconium oxide particles, titanium oxide particles, aluminum oxide particles or zirconium dioxide particles, and the low-refractive-index particles comprise one or more of silver, copper or silicon dioxide.

15. The display panel according to claim 13, wherein a mass ratio of the high-refractive-index particles to the pressure-sensitive adhesive layer ranges from 1% to 40%.

16. The display panel according to claim 12, wherein the refractive index of the light adjusting layer ranges from 1.5 to 2, and the refractive index of the protective layer ranges from 1.1 to 1.4.

17. The display panel according to claim 12, wherein a thickness of the light adjusting layer ranges from 10 microns to 100 microns, and a thickness of the protective layer ranges from 1 micron to 5 microns.

18. The display panel according to claim 11, wherein a cross-sectional shape of the stop block is one of a regular triangle or a regular trapezoid.

19. The display panel according to claim 11, further comprising:
a packaging layer, covering the light emitting layer; and
a touch layer, disposed on the side of the packaging layer away from the substrate, wherein the protective layer is disposed on the side of the touch layer away from the substrate.

20. A display device, comprising a display panel, wherein the display panel comprises:
a substrate;
a light emitting layer, disposed on the substrate and comprising a plurality of light emitting pixels, wherein there is a gap between adjacent two light emitting pixels;
a protective layer, disposed on the side of the light emitting layer away from the substrate, wherein the protective layer comprises a plurality of stop blocks distributed in an array, the plurality of stop blocks are disposed corresponding to the plurality of gaps in one-to-one correspondence; and
a light adjusting layer, disposed between adjacent two stop blocks and covering the stop blocks, wherein a refractive index of the protective layer is less than a refractive index of the light adjusting layer.
